(19) United States
(12) Patent Application Publication
(10) Pub. No.: US 2010/0018753 A1
(43) Pub. Date: Jan. 28, 2010

(54) HIGH VOLTAGE DEVICE, HIGH VOLTAGE BUSHING AND METHOD OF ASSEMBLING SAID DEVICE

(75) Inventors: Tommy L. Larsson, Ludvika (SE); Kerstin M. Ekeroth Reijm, Borlange (SE); Jacob Eltebo, Ludvika (SE); Dan G. Gustavsson, Ludvika (SE); Erik Forsberg, Smedjebacken (SE); Ralf Hartings, Ludvika (SE)

Correspondence Address: VENABLE LLP, P.O. BOX 34385, WASHINGTON, DC, 20043-9998, US

(73) Assignee: ABB TECHNOLGY LTD., Zurich (CH)

(21) Appl. No.: 12/439,559

(22) PCT Filed: Aug. 30, 2007
(86) PCT No.: PCT/SE2007/050595

§ 371 Date: Sep. 14, 2009

(30) Foreign Application Priority Data
Aug. 31, 2006 (SE) 0601783-4

(51) Int. Cl. H01B 17/26; H05K 13/04

(52) U.S. Cl. 174/152 R; 29/729

(57) ABSTRACT

A high voltage device comprises multi contacts as interfaces between internal components and bushings.

### FIELD OF INVENTION

The present invention relates generally to high voltage devices and more particularly to a high voltage device having a bushing arrangement with an improved contact between bushing and the internal lead, which is connected to the active part of the device. The invention also relates to a method of assembling a high voltage device and a high voltage bushing.

### BACKGROUND

It is known that high voltage electrical equipment and devices, such as high voltage transformers, are usually equipped with bushings, which are suitable to carry current at high potential through a grounded barrier, e.g. a transformer tank or a wall.

Conventional bushings are constituted by an insulator made of ceramic or composite material, which is provided with sheds and is generally hollow. The voltage grading can be obtained with or without a condenser body through which the electrical conductor passes.

The electrical devices are conventionally filled with oil acting as insulating and cooling medium inside the device tank, such as a transformer tank. This means that the bushings must be assembled to the device after the oil has been provided, which required special assembly arrangements. One example thereof is a draw rod system, which also allows on-site installation without accessing the leads from inside the transformer main tank. The lower part of the bushing's connection system is left inside the transformer before sealing. During transformer field installation, the draw rod is pushed through the bushing and connected to the bushing's connection system inside the transformer. The bushing is put in place and the bushing's connection system is pulled from the outside by the draw rod to ensure necessary contact force and low through resistance between the transformer internal contact and the bushing bottom contact.

An example of a prior art bushing adapted for use with a high voltage transformer will now be described with reference to FIGS. 1 and 2, wherein FIG. 1 shows the overall structure of the bushing, generally referenced 1, and FIG. 2 is a cross-sectional view of the bushing mounted to a transformer housing made of metal.

A high voltage conductor 10 runs through the center of a hollow bushing insulator 12 that forms a housing around the high voltage conductor. Inside the insulator housing, a condenser core 14 is provided for voltage grading, which is build up around the high voltage conductor 10. A flange 16 is provided to connect the housing of the bushing to ground through a tank assembly housing, schematically shown as 18 in FIG. 2. A ground potential grading shield (not shown) may be mounted to the flange.

The bottom end portion of the high voltage conductor 10 forms a bottom contact 20, which is provided at the lower, bottom end of the bushing 1. The bottom contact 20 is arranged to be connected to a mating internal contact 22 provided in the transformer housing 18. The essentially planar contact interface between the end surface of the bottom contact 20 and the surface of the internal contact 22 is used to interconnect the bushing high voltage conductor 10 and the transformer leads, which are submerged in transformer oil, constituting internal components of the transformer.

An upper outer terminal 24 is provided at the end of the bushing opposite the bottom contact end. This outer terminal 24, which is electrically connected to the high voltage conductor 10 through an essentially planar inter-face, is provided in order to electrically connect the bushing to external sources.

This prior art arrangement of connecting the bushing to the transformer leads relies on correct assembly of the bushing at site, and it is essential that prescribed pressure force is obtained between the planar surface of the bottom contact and the planar surface of the internal contact in order to provide a reliable electrical connection.

### SUMMARY OF THE INVENTION

An object of the present invention is to provide a high quality connection between a bushing and a high voltage device and a method of assembling them, wherein the electrical connection between the bushing and the high voltage device has a high current carrying capacity, exhibits good long-term stability, improvement in the possibilities to use materials of different thermal properties, and which minimizes the risks during assembly on site.

The invention is based on the realization that so-called multi contacts are suitable for use in electrical connections between high voltage bushings and components connected thereto, such as internal high voltage device components submerged in oil, wherein a draw rod system is used for the assembly process.

According to the invention, a high voltage device as defined in appended claim 1, a method of assembling a high voltage device as defined in appended claim 6, and a high voltage bushing as defined in appended claim 8 are provided.

With the inventive arrangement, several advantages are obtained. Since the electrical connection relies on several smaller contact spots instead of one single large area with an undefined number of contact spots, the current carrying capability is improved. An equally important aspect is the possibility of the multi contact to carry current also during movement, which improves the long-term stability. By using the multi contact as a current carrying interface the possibilities of using material combinations with different thermal properties, such as copper to aluminum, can be fully utilized. Finally, since the electrical connection interface to a small degree relies on the axial force applied between the contact surfaces, the risk of assembly mistakes on site is reduced.

In a preferred embodiment, the multi contact is of the so-called spiral contact type, which can work elastically in tangential direction within a range giving the required contact force for each contact spot, increasing reliability and long-term stability.

Further embodiments are defined in the dependent claims.

### BRIEF DESCRIPTION OF DRAWINGS

The invention is now described, by way of example, with reference to the accompanying drawings, in which:

FIG. 1 is an overall view of a prior art high voltage bushing;

FIG. 2 is a cross-sectional view of the bushing of FIG. 1 assembled to a transformer housing;

FIG. 3 is a sectional enlarged view showing the inter-connection of a bushing and the internal lead of a high voltage device according to the invention;

FIG. 4 is a cross-sectional view taken along the line IV-IV in FIG. 3;

FIG. 5 shows a high voltage conductor with a multi contact comprised in the high voltage device according to the invention;

FIG. 6 is a view similar to the one of FIG. 3 but showing an alternative embodiment of a bushing; and

FIG. 7 is a schematic overall view of a high voltage device according to the invention.

### DETAILED DESCRIPTION OF PREFERRED EMBODIMENTS

In the following a detailed description of preferred embodiments of the present invention will be given. In this description, the term “high voltage” will be used for voltages of 10 kV and higher. Today, the upper limit in commercial high voltage devices is 800 kV but even higher voltages, such as 1000 kV or more, are built or envisaged in the near future.

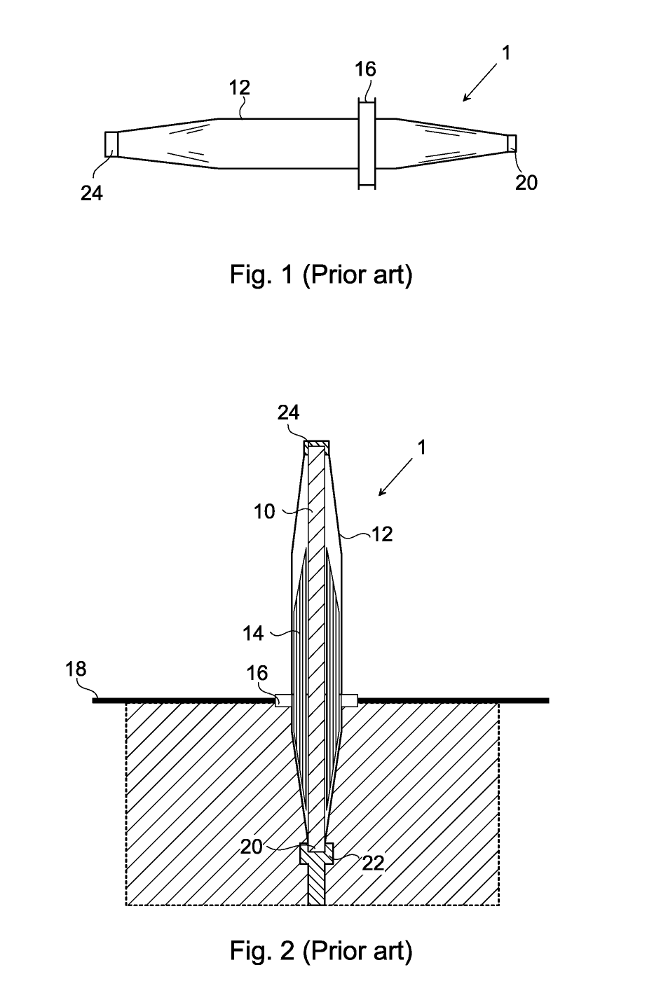

A prior art high voltage bushing arrangement has been described in the background section with reference to FIGS. 1 and 2 and these figures will not be further discussed herein.

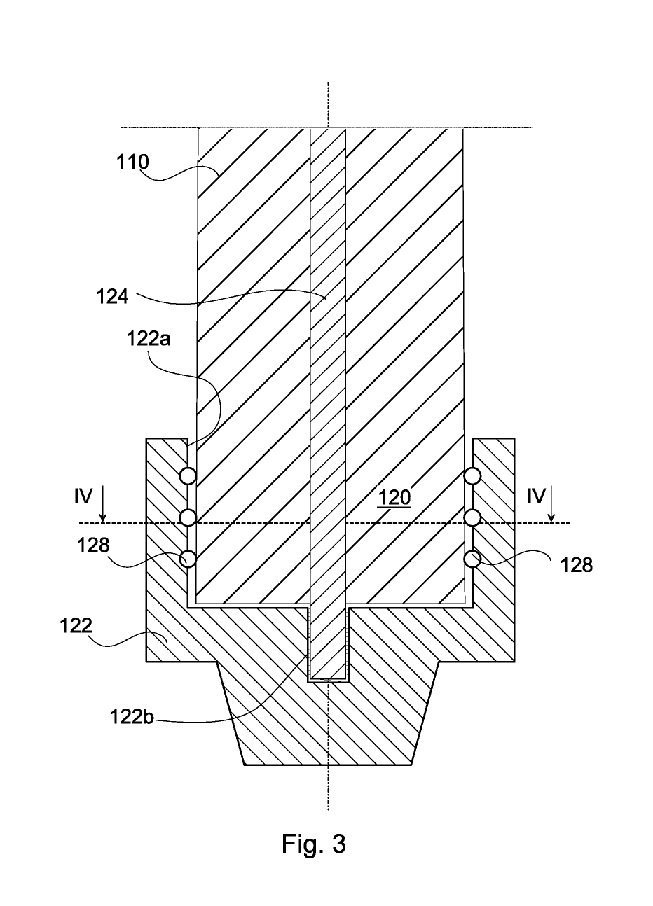

FIG. 3 shows an enlarged view of the electrical connection between lower end portion of the high voltage conductor 110 of the bushing, i.e., the bottom contact 120, and an internal contact 122 of a high voltage transformer lead, i.e., of the electrical connection to windings etc. The bottom contact 120 is similar to the prior art bottom contact 20 described in the background section. The internal contact 122 is however different from the above described prior art bottom contact 122. The inventive internal contact 122 exhibits a cylindrical bore or recess 122a adapted to receive the bottom contact 120 with some radial play. In the bottom surface of the recess 122a, a threaded hole 122b is provided for reception of a correspondingly threaded draw rod 124 used for assembling the high voltage bushing.

The internal contact 122 is submerged in transformer oil.

A so-called multi contact 128 is provided in grooves in the wall of the cylindrical recess 122a, i.e., the multi contact is provided radially outside of the bottom contact 12C and between bottom contact and the internal contact 122. A multi contact is a device that is provided as an interface between two parts that is intended to transfer current between the two parts. The multi contact is made so that a plurality of contact points share the current giving less current for each point.

There are many different designs of the multi contact type. One type of multi contact is the spiral contact, which is made similar to a helical spring with a material with good current carrying properties. The spiral contact can work elastically in tangential direction within a range giving the required contact force for each contact spot. The spiral contact is preferably plated with a material that gives low losses in each contact spot, such as silver.

By means of the provision of the multi contact, reliable electrical connection between the high voltage conductor 10 and the internal contact 122 is obtained, even in the case that the axial force exerted between the high voltage conductor and the internal contact is less than in a conventional draw rod system as described in the background section or if the assembly of the bushing by means of a draw rod arrangement has been assembled without complete axial movement of the high voltage conductor into abutment with the bottom surface of the internal contact recess 122c.

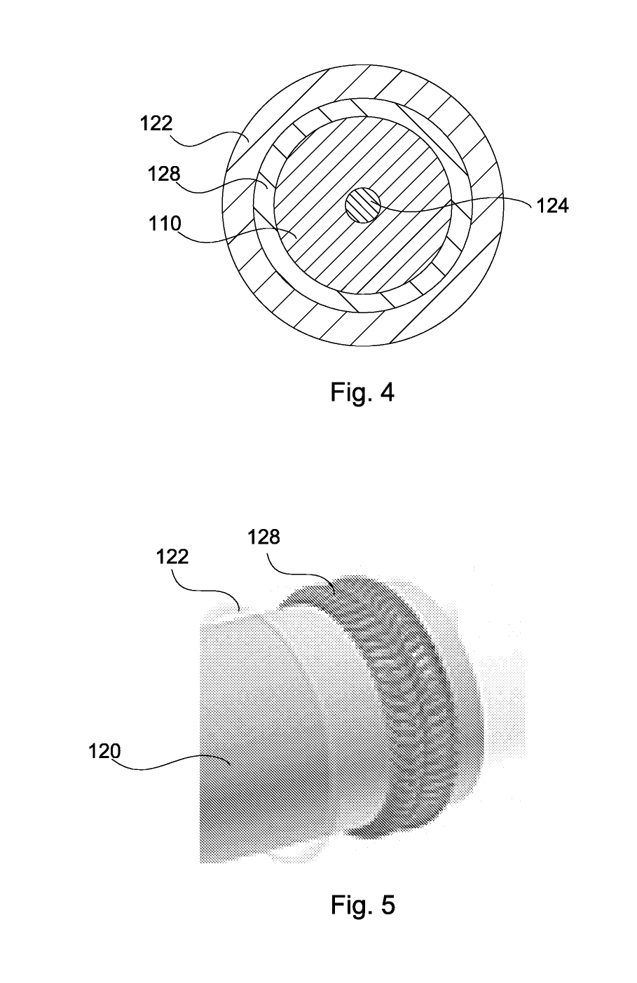

In FIG. 4, a cross-sectional view of the bottom contact 120 and the internal contact 122 taken along the line IV-IV in FIG. 3 is shown. It is here seen that the multi contact 128 forms an interface between the bottom contact 120 of the bushing and the internal contact 122 connected to the transformer lead.

FIG. 5 shows in more detail the multi contact 128, which is of the spiral contact type.

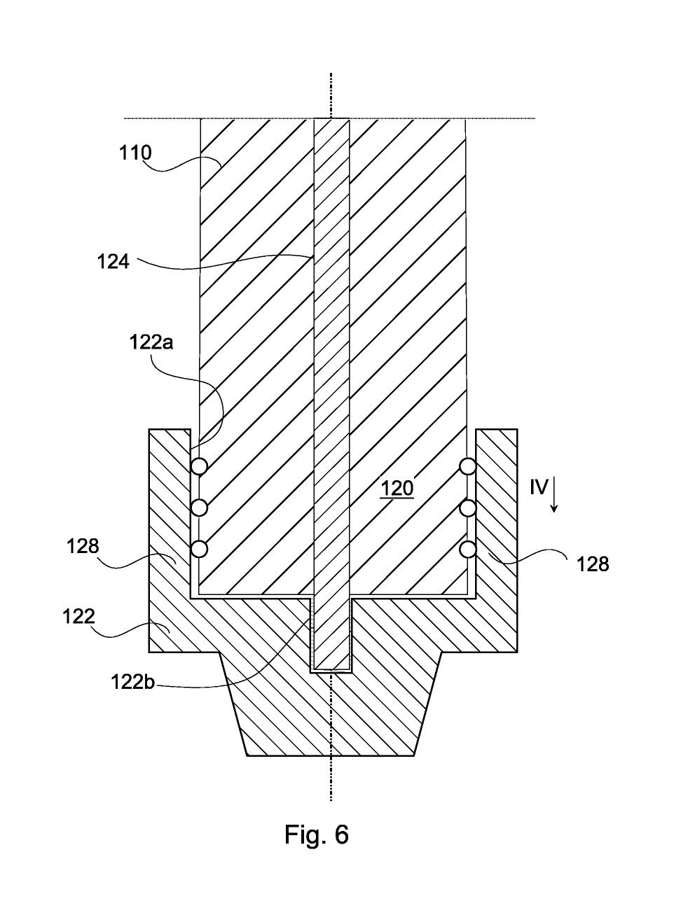

In an alternative embodiment shown in FIG. 6, the multi contact is provided in grooves in the envelope surface of the bottom contact 120 instead of in grooves in the internal contact 122. This means that the multi contact can be attached to the bushing at any suitable time before assembly and that the bushing can be delivered together with the multi contact.

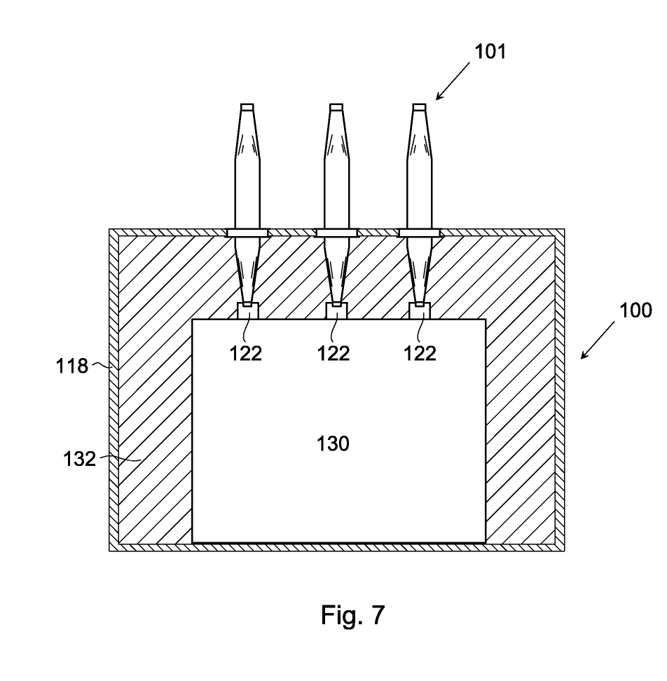

A method of assembling a high voltage device according to the invention will now be described with reference to FIG. 7, which is a schematic overall view through a high voltage transformer. First, the internal components 130 of the transformer, generally referenced 100, such as transformer core and windings, are assembled and then provided with the required number of the above-described internal contact 122 including multi contacts. The internal components are subsequently provided in a transformer housing 118 made of metal, which is then filled with transformer oil 132. The housing is provided with openings adapted for reception of the required number of bushings.

Bushings 101 are subsequently assembled to the transformer housing 118 and connected to the leads of the transformer by means of corresponding contacts 122. This can take place either at a manufacturing plant or, alternatively, on site. During the assembly process, a conventional draw rod system (not shown) is used. The draw rod is firmly attached in the threaded draw rod hole 122b, see FIG. 3, and a tensile force is used to pull the internal contact 122 fully into final position on the bottom contact 120.

Preferred embodiments of a high voltage bushing arrangement and a high voltage transformer according to the invention have been described. A person skilled in the art realizes that these could be varied within the scope of the appended claims. Although the high voltage device to which the inventive high voltage DC bushing is attached has been described as a transformer, it will be appreciated that this device can be other things, such as a reactor, breaker, generator, or other device finding an application in high voltage systems. Also, the high voltage device can comprise one or several bushings.

Although the inventive idea is based on the use of multi contacts for connecting high voltage bushings to the internal leads of a high voltage device by means of a draw rod system, it will be appreciated that the current carrying capacity of the multi contact can be supplemented by the current carrying capacity of the conventional planar interface between the bottom contact of the bushing and the internal contact of the high voltage device.

1. A high voltage device, comprising:
a metal housing;
internal components provided in the metal housing, the internal components being submerged in oil, wherein the internal components are provided with internal electrical contacts;
at least one bushing, which is electrically connected to the internal components by means of a corresponding contact provided at an end of the bushing; and
a multi contact provided as an electrical interface between the bushing and the internal components,
wherein the internal contact includes an attachment configured to attached a draw rod.

2. The high voltage device according to claim 1, wherein the multi contact is provided radially outside of the contact of the bushing.

3. The high voltage device according to claim 1, wherein the multi contact comprises a spiral contact.

4. The high voltage device according to claim 1, wherein the multi contact is provided in grooves in the contact of the bushing

5. The high voltage device according to claim 1, wherein the multi contact is provided in grooves in the contact of the internal components of the device.

6. A method of assembling a high voltage device, the method comprising:
assembling internal components of the device;
providing the internal components in a metal housing;
filling the device with oil;
assembling at least one bushing in electrical contact with the internal components; and
providing a multi contact as electrical interface between the internal components and the bushing,
wherein the step of assembling the at least one bushing is preformed by a draw rod arrangement.

6. The method according to claim 7, wherein the multi contact comprises a spiral contact.

7. A high voltage bushing, comprising:
a metal housing;
a high voltage conductor provided in the housing;
a contact provided at an end of the high voltage conductor; and
a multi contact provided at the contact provided at the end of the high voltage conductor,
wherein the high voltage bushing comprises an attachment configured to attached the bushing to a high voltage device with a draw rod.

8. The high voltage bushing according to claim 8, wherein the multi contact is provided radially outside of the contact provided at an end of the high voltage conductor.
